(19) United States
(12) Patent Application Publication
(10) Pub. No.: US 2010/0301915 A1
(43) Pub. Date: Dec. 2, 2010

(54) LATCH WITH SINGLE CLOCKED DEVICE

(75) Inventors: Jason M. Hart, Hayden, ID (US); Robert P. Masleid, Monte Sereno, CA (US)

Correspondence Address: OSHA LIANG LLP/Oracle, TWO HOUSTON CENTER, 909 FANNIN, SUITE 3500, HOUSTON, TX, 77010, US

(73) Assignee: Sun Microsystems, Inc., Santa Clara, CA (US)

(21) Appl. No.: 12/476,143

(22) Filed: Jun. 1, 2009

(51) Int. Cl. H03K 3/00

(52) U.S. Cl. 327/218

(57) ABSTRACT

A D-latch circuit includes a feed forward circuit, a full keeper circuit, and an output buffer circuit. The feed forward circuit inputs a clock signal and a data signal. The feed forward circuit is connected to an input of the full keeper circuit. The feed forward circuit is connected to an output of the full keeper circuit and an input of the output buffer circuit. The output buffer circuit outputs an output signal. The D-latch consists of a single clocked device that switches with the clock signal.

### BACKGROUND OF INVENTION

Conventional VLSI designs utilize state elements including latches, pulse flops, and master-slave flip flops. Each of these circuits includes clocked loads. Clock power is overhead that does not provide computational results to the end user.

### SUMMARY OF INVENTION

According to one aspect of one or more embodiments of the present invention, a D-latch circuit includes a feed forward circuit, a full keeper circuit, and an output buffer circuit. The feed forward circuit inputs a clock signal and a data signal. The feed forward circuit is connected to an input of the full keeper circuit. The feed forward circuit is connected to an output of the full keeper circuit and an input of the output buffer circuit. The output buffer circuit outputs an output signal. The D-latch circuit consists of a single clocked device that switches with the clock signal.

According to one aspect of one or more embodiments of the present invention, a semiconductor device includes a mechanical package and a semiconductor die. The semiconductor die includes a semiconductor layer, a plurality of metal layers, a clock distribution network that distributes a clock signal within the die, and a D-latch circuit. The D-latch circuit includes a feed forward circuit, a full keeper circuit, and an output buffer circuit. The feed forward circuit inputs the clock signal and a data signal. The feed forward circuit is connected to an input of the full keeper circuit. The feed forward circuit is connected to an output of the full keeper circuit and an input of the output buffer circuit. The output buffer circuit outputs an output signal. The D-latch circuit consists of a single clocked device that switches with the clock signal.

According to one aspect of one or more embodiments of the present invention, a system includes an input device, an output device, a mechanical chassis, a printed circuit board, and a semiconductor device. The semiconductor device includes a mechanical package and a semiconductor die. The semiconductor die includes a semiconductor layer, a plurality of metal layers, a clock distribution network that distributes a clock signal within the die, and a D-latch circuit. The D-latch circuit includes a feed forward circuit, a full keeper circuit, and an output buffer circuit. The feed forward circuit inputs the clock signal and a data signal. The feed forward circuit is connected to an input of the full keeper circuit. The feed forward circuit is connected to an output of the full keeper circuit and an input of the output buffer circuit. The output buffer circuit outputs an output signal. The D-latch circuit consists of a single clocked device that switches with the clock signal.

Other aspects of the present invention will be apparent from the following description and the appended claims.

### BRIEF DESCRIPTION OF DRAWINGS

FIG. 1 shows a system in accordance with one or more embodiments of the present invention.

FIG. 2 shows a printed circuit board that includes one or more semiconductor device(s) that each includes one or more semiconductor die in accordance with one or more embodiments of the present invention.

FIG. 3 shows a conventional 1-bit D-latch circuit with four clocked devices.

FIG. 4 shows a 1-bit D-latch circuit with a single clocked device in accordance with one or more embodiments of the present invention.

FIG. 5 shows a master-slave flip flop made with two 1-bit D-latch circuits in accordance with one or more embodiments of the present invention.

### DETAILED DESCRIPTION

Specific embodiments of the present invention will now be described in detail with reference to the accompanying figures. Like elements in the various figures are denoted by like reference numerals for consistency. Further, in the following detailed description of embodiments of the present invention, numerous specific details are set forth in order to provide a more thorough understanding of the present invention. In other instances, well-known features have not been described in detail to avoid obscuring the description of embodiments of the present invention.

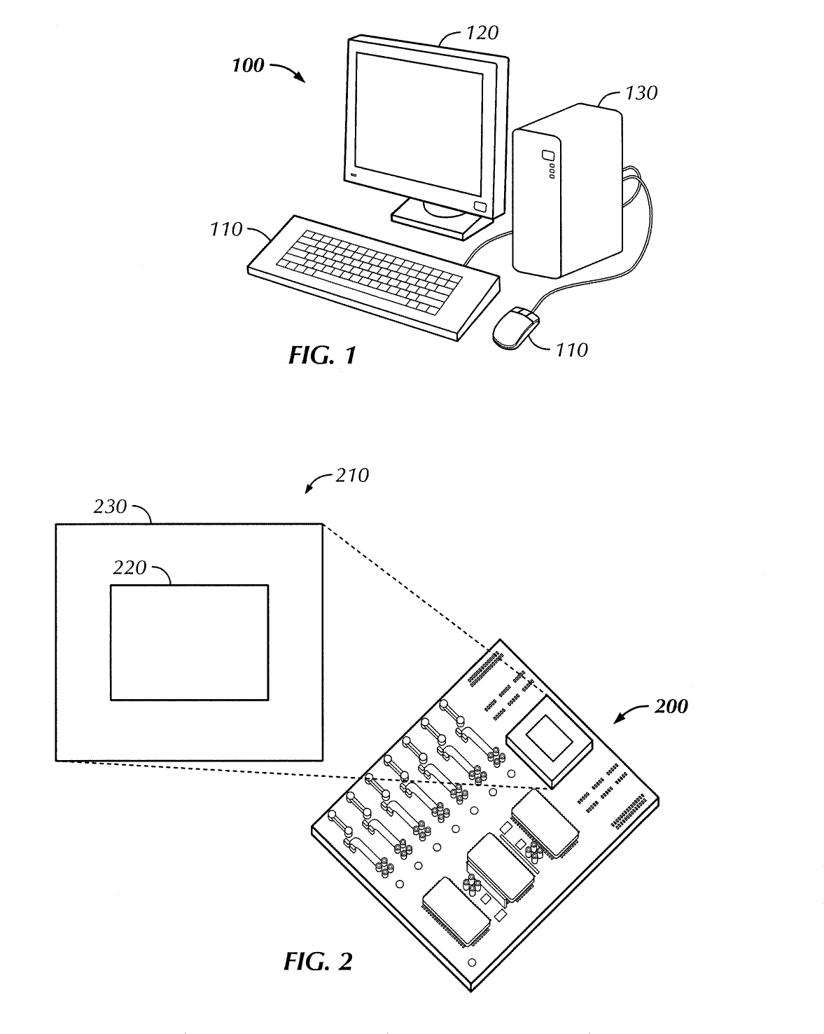

FIG. 1 shows a system in accordance with one or more embodiments of the present invention. A system 100 includes input devices 110, output device 120, and a mechanical chassis 130. The mechanical chassis 130 includes a printed circuit board (“PCB”), a network device, and a storage device (not shown).

FIG. 2 shows a printed circuit board that includes one or more semiconductor device(s) that each includes one or more semiconductor die in accordance with one or more embodiments of the present invention. The PCB 200 may be included in system 100 of FIG. 1 and includes one or more semiconductor device(s) 210. Each semiconductor device 210 includes one or more semiconductor die 220 encapsulated in a mechanical package 230. The mechanical package 230 serves as an electrical and mechanical interface between the die 220 and the PCB 200.

The PCB 200 provides one or more external clock signals to the semiconductor device 210. The mechanical package 230 provides the external clock signal(s) to the die 220. The die 220 is comprised of a plurality of metal layers and a semiconductor layer. The die 220 generates one or more internal clock signals that are a function of the provided external clock signal(s). The internal clock signals are typically the most heavily loaded, the most widely distributed, and the fastest signals within the die 220. Clock distribution networks are used to provide the clock signals to the proper loads within the die 220.

The clock distribution network is organized as a hierarchy of three functional layers that distribute the clock within the semiconductor die: the tree layer, the grid layer, and the local layer. The tree layer includes a fractal clock tree that spans a large area of the die. The grid layer includes clock routes to the individual clock users via a clock grid. The local layer includes clock routes to the actual latches and flip flops.

Latches, pulse flops, and master-slave flip flops include one or more clocked loads. Clocked loads switch twice per clock cycle as compared to logic loads that switch approximately once every ten to twenty clock cycles. As such, clock capacitance is twenty to forty times more important than logic capacitance for the purpose of AC power. Clock power is proportional to the number of clocked devices within a given circuit. In one or more embodiments of the present invention, non-critical path state elements that reduce clock power are disclosed.

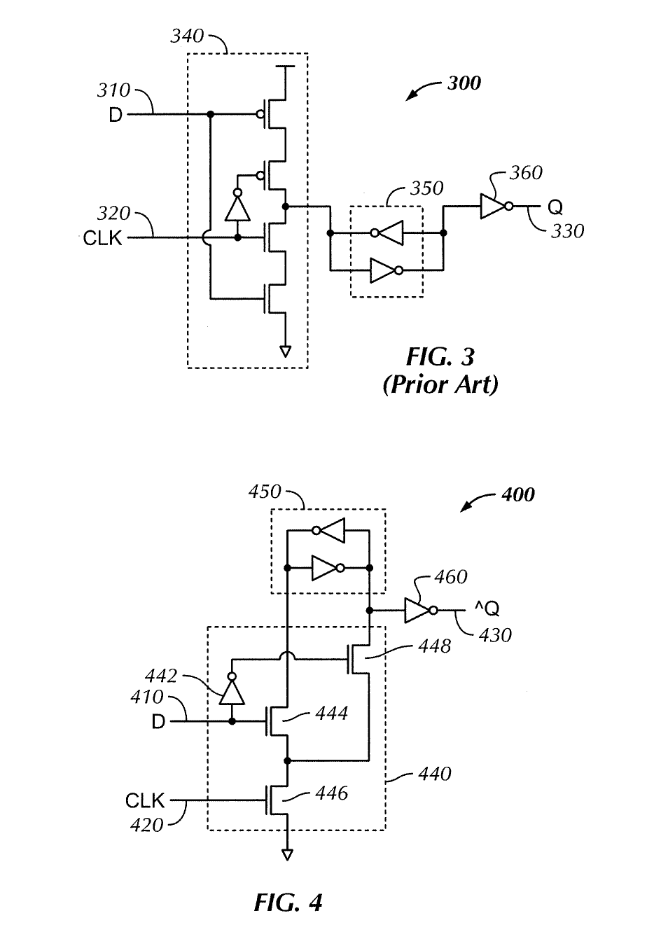

FIG. 3 shows a conventional 1-bit D-latch circuit with four clocked devices. The D-latch circuit 300 inputs a data signal D 310 and a clock signal 320 and outputs an output signal Q 330. The D-latch circuit 300 is transparent-high, meaning that the latch is transparent when the clock 320 is in the high state, and holds state for a half clock cycle when the clock 320 is in the low state. The D-latch circuit 300 includes a tri-state inverter circuit 340 that includes four clocked devices, a full keeper circuit 350, and an output buffer circuit 360. From the perspective of the clock signal 320, the D-latch circuit 300 presents a three device capacitive load. In terms of clock power, the D-latch 300 includes four clocked devices that switch with the clock signal 320.

FIG. 4 shows a 1-bit D-latch circuit with a single clocked device in accordance with one or more embodiments of the present invention. The D-latch circuit 400 inputs a data signal D 410 and a clock signal 420 and outputs an output signal ̂Q 430. One of ordinary skill in the art will recognize that if clock signal 420 is a clock pulse, D-latch circuit 400 functions as a pulse flop in accordance with one or more embodiments of the present invention. The D-latch circuit 400 is transparent-high. From the perspective of inputs and output, D-latch circuit 400 is functionally equivalent to D-latch 300 of FIG. 3 except the output signal ̂Q 430 has the opposite polarity of output signal Q 330. Advantageously, D-latch circuit 400 presents a single capacitive load to clock signal 420 and includes a single clocked device that switches with the clock 420. One of ordinary skill in the art will recognize that D-latch circuit 400 can be implemented with an output signal of either polarity in accordance with one or more embodiments of the present invention. The alternate polarity can be achieved through the use of an additional inverter circuit on the output or an inversion of the circuit in accordance with one or more embodiments of the present invention.

D-latch circuit 400 includes a feed forward circuit 440 that includes a single clocked device, a full keeper circuit 450, and an output buffer circuit 460. The feed forward circuit 440 includes three N-channel field effect transistors (“N-FETs”) 444, 446, and 448 and an inverter circuit 442. One of ordinary skill in the art will recognize that inverter circuit 442 may be comprised of an N-FET and a P-channel field effect transistor in accordance with one or more embodiments of the present invention.

The feed forward circuit 440 inputs data signal D 410 to the input of inverter circuit 442, and the gate of N-FET 444. The clock signal 420 is input to the gate of N-FET 446 only. The drain of N-FET 444 is connected to the input of the full keeper circuit 450. The source of N-FET 444 is connected to the drain of N-FET 446 and the source of N-FET 448. The output of inverter 442 is input to the gate of N-FET 448. The drain of N-FET 448 is connected to the output of the full keeper circuit 450 and output buffer circuit 460. One of ordinary skill in the art will recognize that output buffer circuit 460 may be comprised of an inverter circuit or other suitable buffer circuit in accordance with one or more embodiments of the present invention. Additionally, one of ordinary skill in the art will recognize that the full keeper 450 is fully symmetric with respect to input and output. The output of output buffer circuit 460 is output signal ̂Q 430. From the perspective of the clock signal 420, the D-latch 400 presents a single capacitive load to the clock signal 420 at the gate of N-FET 446. In terms of clock power, D-latch 400 consists of a single clocked device, N-FET 446, that switches with the clock 420. One of ordinary skill in the art will recognize that D-latch circuit 400 could be configured as a multi-bit latch in accordance with one or more embodiments of the present invention. Additionally, one of ordinary skill in the art will recognize that the D-latch circuit 400 could be configured to include a scan latch in accordance with one or more embodiments of the present invention.

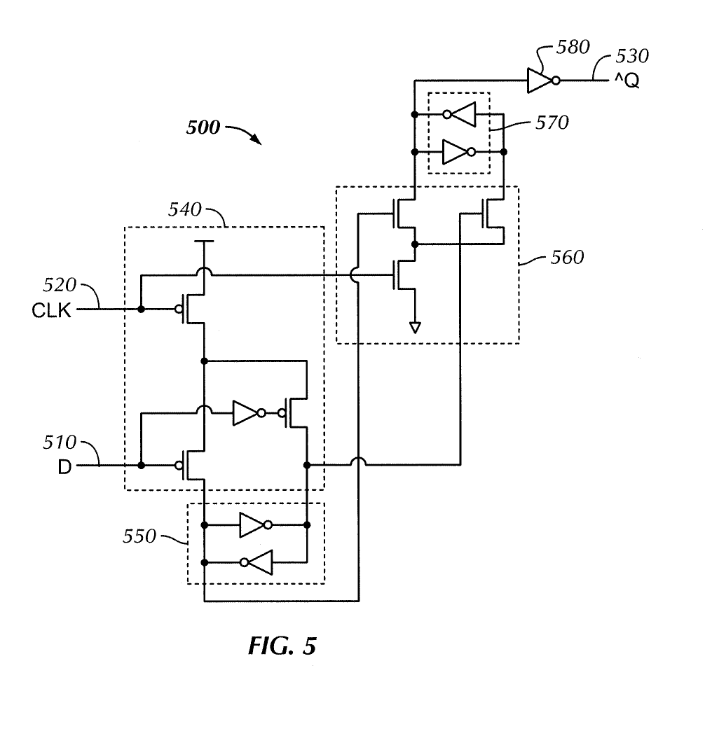

FIG. 5 shows a master-slave flip flop made with two 1-bit D-latches in accordance with one or more embodiments of the present invention. A master-slave flip flop 500 includes two 1-bit D-latches of opposite polarity. The master-slave flip flop 500 inputs a data signal D 510 and a clock signal 520 and outputs an output signal ̂Q 530. The master stage of the master-slave flip flop 500 is an inversion of the 1-bit D-latch of FIG. 4. The master stage includes a master feed forward circuit 540 and a master full keeper circuit 550. The master feed forward circuit 540 is an inversion of the feed forward circuit 440 of FIG. 4. The master full keeper circuit 550 is equivalent to the full keeper circuit 450 of FIG. 4.

The slave stage is a modified version of the 1-bit D-latch of FIG. 4. The slave stage includes a slave feed forward circuit 560 and a slave full keeper circuit 570. The slave feed forward circuit 560 is equivalent to the feed forward circuit 440 of FIG. 4, except slave feed forward circuit 560 does not include the equivalent of inverter circuit 442 of FIG. 4 because slave feed forward circuit 560 has access to both the true and complement of the data signal D 510 in close proximity from the master stage. The slave full keeper circuit 570 is equivalent to the master full keeper circuit 550 and the full keeper circuit 450 of FIG. 4. The master-slave flip flop 500 includes an output buffer circuit 580 that outputs the output signal ̂Q 530.

From the perspective of the clock signal 520, the master-slave flip flop 500 presents a two device capacitive load to the clock signal 520. In terms of clock power, master-slave flip flop 500 includes two clocked devices that switch with the clock 520. One of ordinary skill in the art will recognize that master-slave flip flop 500 could be configured as a multi-bit latch in accordance with one or more embodiments of the present invention.

Advantages of one or more embodiments of the present invention may include one or more of the following.

In one or more embodiments of the present invention, the D-latch circuit consists of a single clocked device that switches with the clock signal.

In one or more embodiments of the present invention, the D-latch circuit presents a single capacitive load to the clock signal.

In one or more embodiments of the present invention, the D-latch circuit functions as a pulse flop when the clock signal is a clock pulse.

In one or more embodiments of the present invention, the D-latch circuit can be combined with a complementary D-latch circuit to form a master-slave flip flop.

In one or more embodiments of the present invention, the D-latch circuit reduces the amount of space required to implement the circuit.

While the invention has been described with respect to a limited number of embodiments, those skilled in the art, having the benefit of this disclosure, will appreciate that other embodiments can be devised which do not depart from the scope of the invention as disclosed herein. Accordingly, the scope of the invention should be limited only by the attached claims.

What is claimed is:

1. A D-latch circuit comprising:
a feed forward circuit;
a full keeper circuit; and
an output buffer circuit;
wherein:
the feed forward circuit inputs a clock signal and a data signal,
the feed forward circuit is connected to an input of the full keeper circuit,
the feed forward circuit is connected to an output of the full keeper circuit and an input of the output buffer circuit,
the output buffer circuit outputs an output signal, and
the D-latch circuit consists of a single clocked device that switches with the clock signal.

2. The D-latch circuit of claim 1, wherein the D-latch circuit presents a single capacitive load to the inputted clock signal.

3. The D-latch circuit of claim 1, wherein the inputted clock signal is pulsed and the D-latch circuit functions as a pulse flop.

4. The D-latch circuit of claim 1, wherein the D-latch circuit is part of a master-slave flip flop.

5. The D-latch circuit of claim 1, wherein the D-latch circuit is a 1-bit latch.

6. A semiconductor device comprising:
a mechanical package; and
a semiconductor die comprising:
a semiconductor layer,
a plurality of metal layers,
a clock distribution network that distributes a clock signal within the die, and
a D-latch circuit comprising:
a feed forward circuit;
a full keeper circuit; and
an output buffer circuit;
wherein:
the feed forward circuit inputs the clock signal and a data signal,
the feed forward circuit is connected to an input of the full keeper circuit,
the feed forward circuit is connected to an output of the full keeper circuit and an input of the output buffer circuit,
the output buffer circuit outputs an output signal, and
the D-latch circuit consists of a single clocked device that switches with the clock signal.

7. The semiconductor device of claim 6, wherein the D-latch circuit presents a single capacitive load to the inputted clock signal.

8. The semiconductor device of claim 6, wherein the inputted clock signal is pulsed and the D-latch circuit functions as a pulse flop.

9. The semiconductor device of claim 6, wherein the D-latch circuit is part of a master-slave flip flop.

10. The semiconductor device of claim 6, wherein the D-latch circuit is a 1-bit latch.

11. A system comprising:
an input device;
an output device;
a mechanical chassis;
a printed circuit board; and
a semiconductor device comprising:
a mechanical package, and
a semiconductor die;
wherein the semiconductor die comprises:
a semiconductor layer,
a plurality of metal layers,
a clock distribution network that distributes a clock signal within the die, and
a D-latch circuit comprising:
a feed forward circuit;
a full keeper circuit; and
an output buffer circuit;
wherein:
the feed forward circuit inputs the clock signal and a data signal,
the feed forward circuit is connected to an input of the full keeper circuit,
the feed forward circuit is connected to an output of the full keeper circuit and an input of the output buffer circuit,
the output buffer circuit outputs an output signal, and
the D-latch circuit consists of a single clocked device that switches with the clock signal.

12. The system of claim 11, wherein the D-latch circuit presents a single capacitive load to the inputted clock signal.

13. The system of claim 11, wherein the inputted clock signal is pulsed and the D-latch circuit functions as a pulse flop.

14. The system of claim 11, wherein the D-latch circuit is part of a master-slave flip flop.

15. The system of claim 11, wherein the D-latch circuit is a 1-bit latch.
